(19) United States
(12) Patent Application Publication
(10) Pub. No.: US 2017/0207329 A1
(43) Pub. Date: Jul. 20, 2017

(54) EPITAXIAL WAFER FOR HETEROJUNCTION BIPOLAR TRANSISTOR AND HETEROJUNCTION BIPOLAR TRANSISTOR

(71) Applicant: SUMITOMO CHEMICAL COMPANY, LIMITED, Tokyo (JP)

(72) Inventor: Shinjiro FUJIO, Hitachi-shi, Ibaraki (JP)

(73) Assignee: SUMITOMO CHEMICAL COMPANY, LIMITED, Tokyo (JP)

(21) Appl. No.: 15/313,825

(22) PCT Filed: May 26, 2015
(86) PCT No.: PCT/JP2015/065061

§ 371 Date: Nov. 23, 2016

(30) Foreign Application Priority Data
May 26, 2014 (JP) 2014-108048

(51) Int. Cl. H01L 29/737; H01L 29/10; H01L 29/66; H01L 29/205

(52) U.S. Cl. CPC H01L 29/7378; H01L 29/205; H01L 29/1004; H01L 29/66242

(57) ABSTRACT

An epitaxial wafer for a heterojunction bipolar transistor and a heterojunction bipolar transistor that is capable of reducing a base resistance and a turn-on voltage as compared to a conventional technique are provided. In an epitaxial wafer for a heterojunction bipolar transistor that includes a collector layer made of GaAs, a base layer (second base layer) formed on the collector layer and made of InGaAs, and an emitter layer formed on the second base layer and made of InGaP, a base layer (first base layer) made of GaAs is interposed between the collector layer and the second base layer.

### TECHNICAL FIELD

The present invention relates to an epitaxial wafer for a semiconductor transistor and to the semiconductor transistor and, in particular, relates to an epitaxial wafer for a heterojunction bipolar transistor and to a heterojunction bipolar transistor.

### BACKGROUND ART

As a heterojunction bipolar transistor (HBT) in which a group III-V compound semiconductor is used, an InGaP/GaAs heterojunction bipolar transistor is widely used in which an emitter layer made of InGaP, which is a wide band gap semiconductor, is employed and other layers are made of GaAs in order to increase the current gain and the current injection efficiency.

In such an InGaP/GaAs heterojunction bipolar transistor, employing a base layer made of InGaAs having a smaller band gap than GaAs makes it possible to reduce a turn-on voltage (see, for example, Patent Literatures 1 and 2).

### LISTING OF REFERENCES

PATENT LITERATURE 1: Japanese Patent Application Laid-Open Publication (Kokai) No. 2003-273118 A

PATENT LITERATURE 2: Japanese Patent Application Laid-Open Publication (Kokai) No. 2005-150487 A

### SUMMARY OF THE INVENTION

### Problems to be Solved by the Invention

As described above, employing a base layer made of InGaAs, instead of a base layer made of GaAs, makes it possible to reduce a turn-on voltage. In this case, however, the lattice constant of InGaAs constituting the base layer differs from the lattice constant of GaAs constituting other layers (except for an emitter layer), and thus accumulation of distortion increases as the film thickness of the base layer increases.

When the film thickness of the base layer exceeds a certain film thickness (hereinafter, referred to as a “critical film thickness”), accumulation of distortion becomes intolerable, and a dislocation occurs in order to mitigate the distortion. As a result, the occurrence of a dislocation degrades the crystallinity, which in turn results in an increase in a turn-on voltage.

Therefore, as compared to a base layer made of GaAs, it is not possible to increase the film thickness of a base layer made of InGaAs, which results in a problem that the base resistance increases.

As a method of reducing the base resistance, it is conceivable to increase the carrier concentration of the base layer, but an increase in the carrier concentration leads to an increase in the recombination current, which leads to a decrease in the current gain. Thus, such a method cannot be adopted.

Taking the above mentioned circumstances into account, accordingly, the present invention is directed to providing an epitaxial wafer for a heterojunction bipolar transistor and a heterojunction bipolar transistor that are capable of further reducing a base resistance and a turn-on voltage, as compared to the conventional technique.

### Solution To Overcome The Problems

The present invention made to achieve the above mentioned object provides an epitaxial wafer for a heterojunction bipolar transistor. According to one aspect of the present invention, there is provided an epitaxial wafer including a collector layer made of GaAs, a base layer made of InGaAs, and an emitter layer made of InGaP, and another base layer made of GaAs is interposed between the collector layer made of GaAs and the base layer made of InGaAs.

According to another aspect of the present invention, it is preferable that the base layer made of GaAs have a film thickness of equal to or less than 20 nm.

According to yet another aspect of the present invention, it is preferable that the base layer made of InGaAs have a film thickness of equal to or less than a critical film thickness.

According to yet another aspect of the present invention, it is preferable that the base layer made of InGaAs have an In composition of no less than 0.16 nor more than 0.21.

According to yet another aspect of the present invention, there is also provided a heterojunction bipolar transistor fabricated with the use of the epitaxial wafer for the heterojunction bipolar transistor.

### BRIEF DESCRIPTION OF THE DRAWINGS

FIG. 1 is a schematic diagram illustrating a structure of an epitaxial wafer for a heterojunction bipolar transistor according to an embodiment of the present invention.

FIG. 2 is a schematic diagram illustrating a structure of a heterojunction bipolar transistor according to an embodiment of the present invention.

FIG. 3 is a schematic diagram illustrating a structure of an epitaxial wafer for a heterojunction bipolar transistor fabricated in order to define a preferable range for the In composition of a second base layer.

FIG. 4 illustrates a relationship between a turn-on voltage and an In composition of the second base layer when the In composition of the second base layer is varied.

FIG. 5 illustrates a relationship between a turn-on voltage and a base resistance when the film thickness of a first base layer is varied.

### MODE FOR CARRYING OUT THE INVENTION

Hereinafter, preferred embodiments of the present invention will be described in detail with reference to the appended drawings.

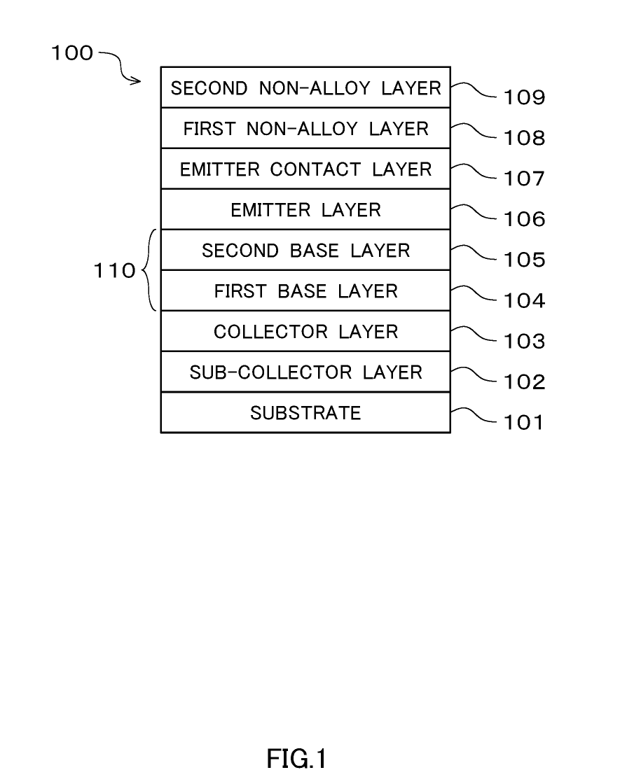

As illustrated in FIG. 1, an epitaxial wafer 100 for a heterojunction bipolar transistor according to a preferred embodiment of the present invention includes a substrate 101 made of a semi-insulating GaAs, a sub-collector layer 102 formed on the substrate 101 and made of GaAs, a collector layer 103 formed on the sub-collector layer 102 and made of GaAs, a first base layer 104 formed on the collector layer 103 and made of GaAs, a second base layer 105 formed on the first base layer 104 and made of InGaAs, an emitter layer 106 formed on the second base layer 105 and made of InGaP, an emitter contact layer 107 formed on the emitter layer 106 and made of GaAs, a first non-alloy layer 108 formed on the emitter contact layer 107 and made of InGaAs, and a second non-alloy layer 109 formed on the first non-alloy layer 108 and made of InGaAs.

In other words, in order to solve the problem of an epitaxial wafer for a heterojunction bipolar transistor according to a conventional technique in which an emitter layer 106 is made of InGaP, a base layer (i.e., second base layer 105) is made of InGaAs, other layers are primarily made of GaAs, and the layers are epitaxially grown in order from the bottom layer to the top layer, in the epitaxial wafer 100 for a heterojunction bipolar transistor, a base layer made of GaAs (i.e., first base layer 104) is disposed underneath the second base layer 105, or in other words, interposed between the collector layer 103 and the second base layer 105.

The lattice constant of the first base layer 104 is equal to the lattice constant of GaAs constituting the collector layer 103 underneath the first base layer 104. For this reason, even when the film thickness of the first base layer 104 is increased, distortion is less likely to accumulate, and a dislocation hardly occurs. Therefore, when it is assumed that a base layer 110 of a dual-layer structure consisting of the first base layer 104 and the second base layer 105 is formed, by inserting the first base layer 104 underneath the second base layer 105, an effect provided by employing the second base layer 105, or in other words, an effect of reducing the turn-on voltage is obtained, and the film thickness of the base layer 110 as a whole can be increased, so as to provide an effect of reducing the base resistance of the base layer 110 as well.

However, it is not always true that the film thickness of the first base layer 104 may be increased unlimitedly in order to reduce the base resistance of the base layer 110. In this regard, when the film thickness of the first base layer 104 is increased to more than 20 nm, the turn-on voltage inevitably increases.

The cause for this could be as follows. When the film thickness of the first base layer 104 is increased to more than 20 nm, this exceeds the diffusion length of electrons, which are minority carriers, and the electrons become unable to go over the energy barrier formed between the first base layer 104 and the second base layer 105, leading to a decrease in the current.

For this reason, it is preferable that the first base layer 104 have a film thickness of equal to or less than 20 nm, so that the base resistance can be reduced while retaining the effect of reducing the turn-on voltage to be obtained by employing the second base layer 105.

As described above, when the film thickness of the second base layer 105 exceeds the critical film thickness, the accumulation of distortion becomes intolerable, and a dislocation occurs in order to mitigate the distortion. The occurrence of the dislocation degrades the crystallinity, which results in an increase in the turn-on voltage. Therefore, in order to prevent an increase in the turn-on voltage arising due to an occurrence of a dislocation, it is preferable that the second base layer 105 have a film thickness of equal to or less than the critical film thickness.

In addition, the turn-on voltage decreases as the In composition of InGaAs constituting the second base layer 105 increases, and the turn-on voltage reaches a minimum when the In composition is 0.18. When the In composition increases even further, the turn-on voltage rises inversely. For this reason, as a range in which the turn-on voltage can be kept low, it is preferable that the second base layer 105 have an In composition of no less than 0.16 nor more than 0.21.

With the configuration described above, according to the epitaxial wafer 100 for a heterojunction bipolar transistor according to the present embodiment, the base resistance and the turn-on voltage can be reduced as compared to a conventional technique.

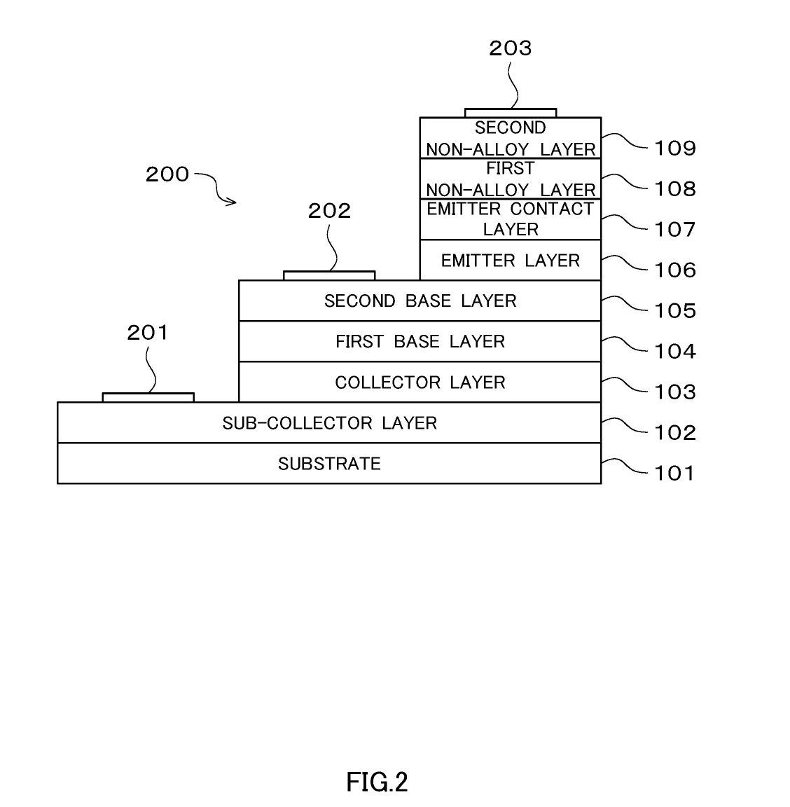

As illustrated in FIG. 2, while using the epitaxial wafer 100 for a heterojunction bipolar transistor, a heterojunction bipolar transistor 200 can be obtained by forming a collector electrode 201 on the sub-collector layer 102, forming a base electrode 202 on the second base layer 105, and forming an emitter electrode 203 on the second non-alloy layer 109.

According to this heterojunction bipolar transistor 200, the base resistance and the turn-on voltage can be further reduced, as compared to the conventional technique.

### CONCRETE EXAMPLES

Hereinafter, the basis for the numerical limitations according to the present invention will be described.

Herein, “n” is affixed when an epitaxial layer is of n-type, and “p” is affixed when an epitaxial layer is of p-type. In addition, a case in which the impurity density is relatively high is indicated by “⁺,” and a case in which the impurity density is relatively low is indicated by “⁻”

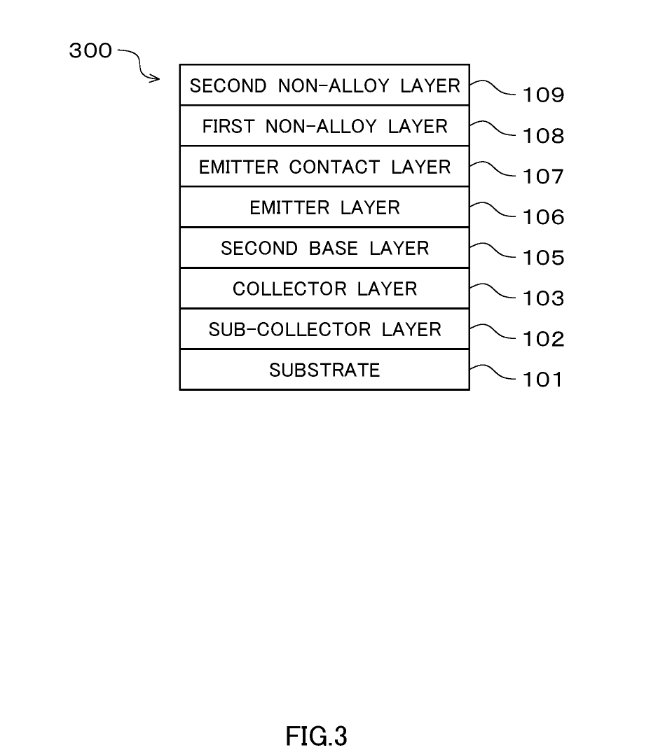

Inventors of the present invention fabricated an epitaxial wafer 300 for a heterojunction bipolar transistor that does not include the first base layer 104 through a metal organic vapor phase epitaxy (MOVPE) method by, as shown in FIG. 3, epitaxially growing in order, on a substrate 101 made of semi-insulating GaAs, a sub-collector layer 102 made of n⁺-GaAs, a collector layer 103 made of n⁻-GaAs, a second base layer 105 made of p⁺-InₓGa₁₋ₓAs, an emitter layer made 106 of n⁻-InGaP, an emitter contact layer 107 made of n⁺-GaAs, a first non-alloy layer made of n⁺-In_{0.5}Ga_{0.5}As, and a second non-alloy layer made of n⁺-In_{0.5→0}Ga_{0.5→1}As.

Fabricated were the epitaxial wafers 300 for a heterojunction bipolar transistor in each of which the sub-collector layer 102 had a film thickness of 500 nm and a carrier concentration of 3×10¹⁸ cm⁻³, the collector layer 103 had a film thickness of 500 nm and a carrier concentration of 1×10¹⁶ cm⁻³, the second base layer 105 had a film thickness of 50 nm and a carrier concentration of 4×10¹⁹ cm⁻³, the emitter layer 106 had a film thickness of 30 nm and a carrier concentration of 3×10¹⁷ cm⁻³, the emitter contact layer 107 had a film thickness of 100 nm and a carrier concentration of 3×10¹⁸ cm⁻³, the first non-alloy layer 108 had a film thickness of 40 nm and a carrier concentration of 2×10¹⁹ cm⁻³, the second non-alloy layer 109 had a film thickness of 40 nm and a carrier concentration of 2×10¹⁹ cm⁻³, and the second base layer 105 had an In composition x that was varied among 0.10, 0.12, 0.14, 0.16, 0.18, 0.20, 0.21 and 0.22. The turn-on voltage of each of these epitaxial wafers 300 for a heterojunction bipolar transistor was then measured.

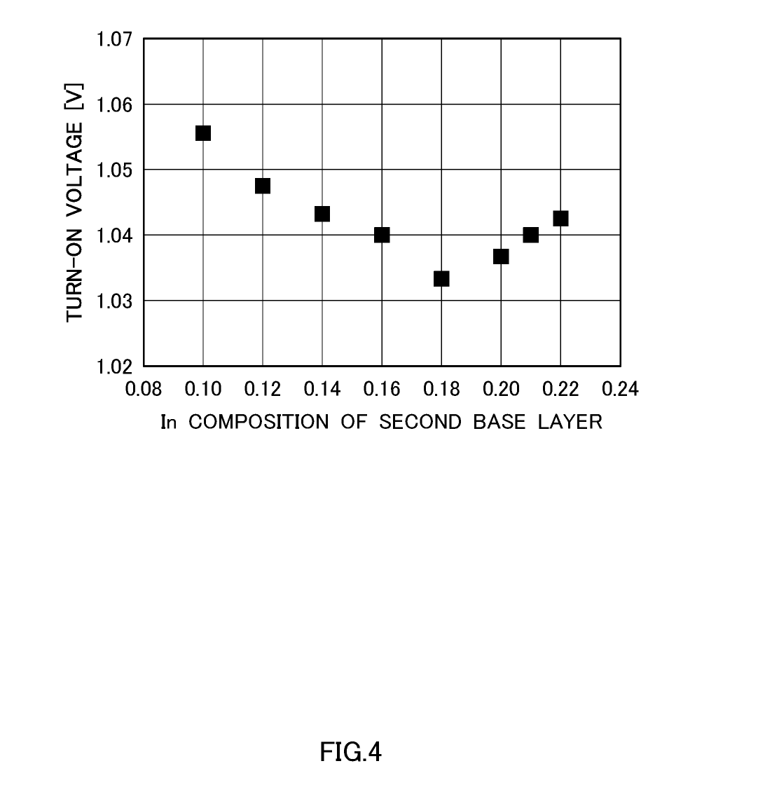

As can be seen from FIG. 4, the turn-on voltage decreases as the In composition x of the second base layer 105 increases, and the turn-on voltage reaches a minimum when the In composition x is 0.18. When the In composition x increases even further, the turn-on voltage rises inversely.

On the basis of the above results, in the present invention, as a range in which the turn-on voltage can be kept to equal to or less than 1.04 V, the In composition x of the second base layer 105 is set to no less than 0.16 nor more than 0.21.

Next, an epitaxial wafer 100 for a heterojunction bipolar transistor in which a first base layer 104 made of p⁺-GaAs was inserted underneath the second base layer 105 was fabricated.

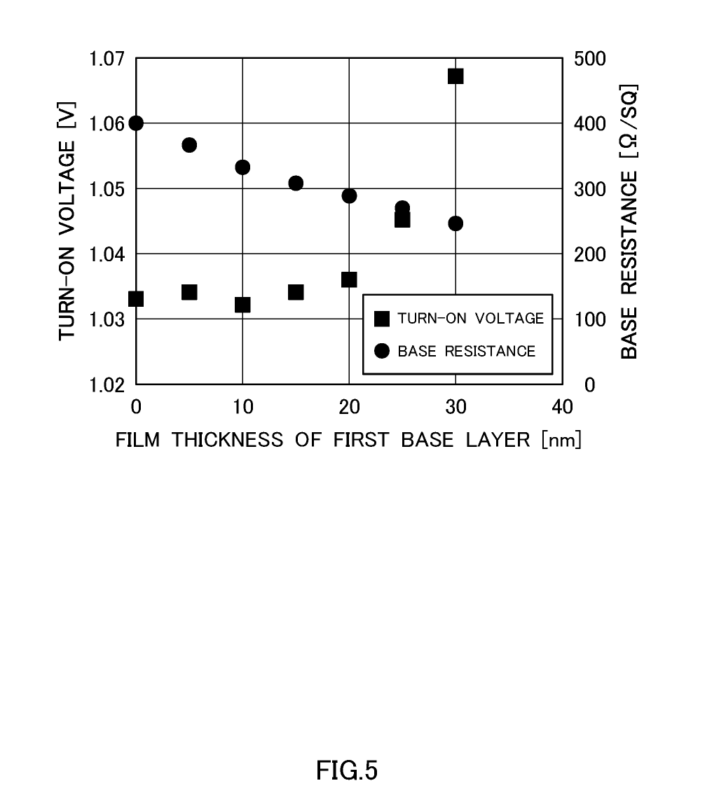

Here, epitaxial wafers 100 for a heterojunction bipolar transistor in which the carrier concentration of the first base layer 104 was set to 4×10¹⁹ cm⁻³, the In composition x of the second base layer 105 was fixed at 0.18 on the basis of the above results, and the film thickness of the first base layer 104 was varied among 0 nm, 5 nm, 10 nm, 15 nm, 20 nm, 25 nm, and 30 nm were fabricated, and the turn-on voltages and the base resistances of these epitaxial wafer 100 for a heterojunction bipolar transistor were measured. The results are shown in FIG. 5.

As can be seen from FIG. 5, as the film thickness of the first base layer 104 increases, the base resistance decreases, but the turn-on voltage increases. When the film thickness of the first base layer 104 exceeds 20 nm, the turn-on voltage becomes greater than that of an epitaxial wafer 300 for a heterojunction bipolar transistor according to a conventional technique.

On the basis of the above results, in the present invention, the film thickness of the first base layer 104 is set to equal to or less than 20 nm. In particular, by setting the film thickness of the first base layer 104 to 20 nm, the base resistance can be reduced by as much as approximately 30% while retaining the effect of reducing the turn-on voltage.

1. An epitaxial wafer for a heterojunction bipolar transistor, the epitaxial wafer comprising:
a collector layer made of GaAs;
a base layer formed on the collector layer and made of InGaAs; and
an emitter layer formed on the base layer and made of InGaP, and
a base layer made of GaAs being interposed between the collector layer and the base layer.

2. The epitaxial wafer for a heterojunction bipolar transistor according to claim 1,
wherein the base layer made of GaAs has a film thickness of equal to or less than 20 nm.

3. The epitaxial wafer for a heterojunction bipolar transistor according to claim 1,
wherein the base layer made of InGaAs has a film thickness of equal to or less than a critical film thickness.

4. The epitaxial wafer for a heterojunction bipolar transistor according to claim 1,
wherein the base layer made of InGaAs has an In composition of no less than 0.16 nor more than 0.21.

5. A heterojunction bipolar transistor fabricated with the use of the epitaxial wafer for a heterojunction bipolar transistor according to claim 1.

6. The epitaxial wafer for a heterojunction bipolar transistor according to claim 2,
wherein the base layer made of InGaAs has a film thickness of equal to or less than a critical film thickness.

7. The epitaxial wafer for a heterojunction bipolar transistor according to claim 2, wherein the base layer made of InGaAs has an In composition of no less than 0.16 nor more than 0.21.

8. The epitaxial wafer for a heterojunction bipolar transistor according to claim 3, wherein the base layer made of InGaAs has an In composition of no less than 0.16 nor more than 0.21.

9. A heterojunction bipolar transistor fabricated with the use of the epitaxial wafer for a heterojunction bipolar transistor according to claim 2.

10. A heterojunction bipolar transistor fabricated with the use of the epitaxial wafer for a heterojunction bipolar transistor according to claim 3.

11. A heterojunction bipolar transistor fabricated with the use of the epitaxial wafer for a heterojunction bipolar transistor according to claim 4.
